(19) United States
(12) Patent Application Publication
(10) Pub. No.: US 2026/0004994 A1
(43) Pub. Date: Jan. 1, 2026

(54) PULSE GENERATOR

(71) Applicant: Samsung Electronics Co., Ltd., Suwon-si (KR)

(72) Inventors: Hwa Soo SEOK, Suwon-si (KR); Yong Won CHO, Suwon-si (KR); Kyung-Sun KIM, Suwon-si (KR); Nam Kyun KIM, Suwon-si (KR); Sung-Yeol KIM, Suwon-si (KR); Mee Hyun LIM, Suwon-si (KR)

(73) Assignee: Samsung Electronics Co., Ltd., Suwon-si (KR)

(21) Appl. No.: 18/999,345

(22) Filed: Dec. 23, 2024

(30) Foreign Application Priority Data
Jul. 1, 2024 (KR) 10-2024-0086010

(51) Int. Cl. H01J 37/32

(52) U.S. Cl. CPC H01J 37/32146; H01J 37/32174

(57) ABSTRACT

According to some example embodiments, a pulse generator includes a first constant voltage generator connected to a first voltage node, a second constant voltage generator connected to a second voltage node, a first switch connected between the first voltage node and a first node, a second switch connected between the first node and a third node, a third switch connected between the third node and a second node, a fourth switch connected between the second node and the second voltage node, and a clamping circuit connected between at least one of the first node and the second node and an output node, and configured to reduce an overshoot of an output voltage that is output through the third node and the output node.

### CROSS-REFERENCE TO RELATED APPLICATION

This application claims priority under 35 U.S.C. § 119 to Korean Patent Application No. 10-2024-0086010 filed on Jul. 1, 2024, in the Korean Intellectual Property Office, the entire contents of which are herein incorporated by reference.

### BACKGROUND

Example embodiments are directed a pulse generator.

In a substrate processing device using plasma, a bias voltage is used to control an ion directionality of the plasma. The bias voltage exhibits a signal overshoot and this makes the operation of the substrate processing device unstable and/or unreliable. For example, when a high voltage is applied to a wafer and/or a chuck and arcing and/or overshoot occurs, the wafer and/or the chuck may be damaged. In addition, the signal overshoot may increase electromagnetic interference (EMI) noise and cause erroneous operation of the components of the substrate processing device due to electromagnetic interference. Since ions of the plasma are subjected or exposed to a non-uniform bias electric field, a deviation of the ion energy distribution function (IEDF) of the ions increases, which may deteriorate and/or reduce a process profile quality.

### SUMMARY

Some example embodiments of the present disclosure are directed to a pulse generator configured to minimize an overshoot component of an output voltage.

Some example embodiments of the present disclosure are directed to a substrate processing device including a pulse generator configured to minimize an overshoot component of an output voltage.

According to some example embodiments of the present disclosure, a pulse generator may include a first constant voltage generator connected to a first voltage node, a second constant voltage generator connected to a second voltage node, a first switch connected between the first voltage node and a first node, a second switch connected between the first node and a third node, a third switch connected between the third node and a second node, a fourth switch connected between the second node and the second voltage node, and a clamping circuit connected between at least one of the first node and the second node and an output node, and configured to reduce an overshoot of an output voltage that is output through the third node and the output node.

According to some example embodiments of the present disclosure, a pulse generator includes a constant voltage source including a first constant voltage generator and a second constant voltage generator, a pulse generating circuit including a first switch connected between a first node and the first constant voltage generator, a second switch connected between the first node and a third node, a third switch connected between the third node and a second node, a fourth switch connected between the second node and the second constant voltage generator, a first diode connected between a ground and the first node, and a second diode connected between the ground and the second node, and a clamping circuit including a first clamping diode connected between the first node and an output node, a second clamping diode connected between the second node and the output node, and an inductor connected between the third node and the output node. An output voltage is output through the output node, and the output voltage includes signals generated by sequentially switching between a first switching state, a second switching state, and a third switching state, in the first switching state, the first switch and the second switch are configured to be in an on state, and the third switch and the fourth switch are configured to be in an off state, in the second switching state, the first switch is configured to be in an on state, and the second switch, the third switch, and the fourth switch are configured to be in an off state, and in the third switching state, the second switch and the third switch are configured to be in an on state, and the first switch and the fourth switch are configured to be in an off state.

According to some example embodiments of the present disclosure, a pulse generator includes a first constant voltage generator connected to a first voltage node, a second constant voltage generator connected to a second voltage node, a first switch connected between the first voltage node and a first node, a second switch connected between the first node and a third node, a third switch connected between the third node and a second node, a fourth switch connected between the second node and the second voltage node, a first clamping diode connected between the first node and an output node, and a second clamping diode connected between the second node and the output node. Each of the first, second, third and fourth switches includes a MOS transistor, when the first switch and the second switch are configured to be in an on state, the pulse generator is configured to output an output voltage through the first switch, the second switch, the third node, and the output node, and when the second switch is configured to be in an off state, a current is supplied to the second constant voltage generator and the first constant voltage generator through the second voltage node, a body diode of the fourth switch, a body diode of the third switch, the output node, the first clamping diode, and a body diode of the first switch.

### BRIEF DESCRIPTION OF THE DRAWINGS

The above and other aspects and features of the present disclosure will become more apparent by describing in detail example embodiments thereof with reference to the attached drawings, in which:

FIG. 1 is a block diagram of a pulse generator, according to some example embodiments of the present disclosure.

FIG. 2 is a circuit diagram of the pulse generator of FIG. 1, according to some example embodiments.

FIG. 3 illustrates a technical effect obtained from the pulse generator of FIG. 1.

FIG. 4 is a timing diagram of a three-level pulse generated according to a change in a switching state of the pulse generator.

FIG. 5 is a timing diagram of a bipolar pulse generated according to a change in the switching state of the pulse generator.

FIG. 6 is a timing diagram of a unipolar pulse generated according to a change in the switching state of the pulse generator.

FIG. 7 is a timing diagram of a unipolar pulse generated according to a change in the switching state of the pulse generator.

FIG. 8 is a timing diagram of a three-level pulse generation operation of the pulse generator.

FIG. 9 illustrates a mode analysis of the pulse generator in a switching state P.

FIG. 10 illustrates a mode analysis of the pulse generator in a switching state O.

FIG. 11 illustrates a mode analysis of the pulse generator in a switching state N.

FIG. 12 is a timing diagram of a three-level pulse generated with energy regeneration according to a change in the switching state of the pulse generator.

FIG. 13 is a timing diagram of a three-level pulse generation operation in which energy regeneration is performed together.

FIGS. 14A and 14B illustrate a mode analysis of the pulse generator in a switching state P′.

FIGS. 15A and 15B illustrate a mode analysis of the pulse generator in a switching state N′.

FIGS. 16, 17, 18, and 19 illustrate circuit diagrams of different pulse generators, according to some example embodiments of the present disclosure.

FIG. 20 is a timing diagram of a feedback operation of the pulse generator according to some example embodiments of the present disclosure.

FIG. 21 is an example block diagram for feedback control of a first constant voltage V_{DC1} of the pulse generator according to some example embodiments of the present disclosure.

FIG. 22 is an example block diagram for feedback control of a second constant voltage V_{DC2} of the pulse generator according to some example embodiments of the present disclosure.

FIG. 23 is a block diagram of a substrate processing device, according to some example embodiments of the present disclosure.

### DETAILED DESCRIPTION

Hereinafter, example embodiments of the present disclosure will be described in detail with reference to the accompanying drawings. The same reference numerals are used for the same components in the drawings, and duplicate descriptions thereof are omitted.

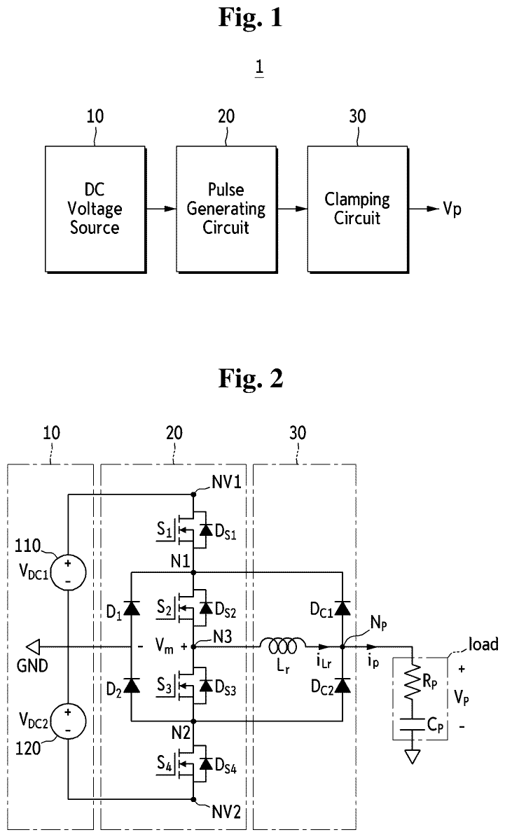

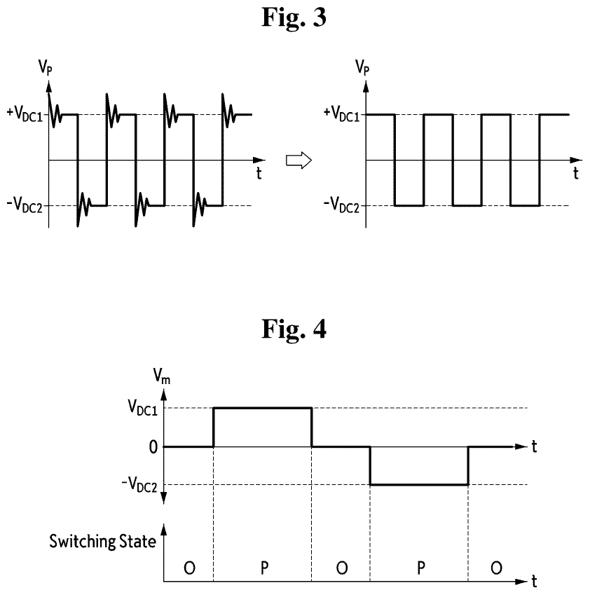

FIG. 1 is a block diagram of a pulse generator, according to some example embodiments. FIG. 2 is circuit diagram of the pulse generator of FIG. 1, according to some example embodiments. FIG. 3 illustrates a technical effect obtained from the pulse generator of FIG. 1.

First, referring to FIG. 1, a pulse generator 1, according to some example embodiments, may include a constant voltage source 10, a pulse generating circuit 20, and a clamping circuit 30. The pulse generator 1 may be controlled by a controller to generate an output voltage Vp. The controller may control a switching operation, for example, by controlling the on and off operation of each switch.

The constant voltage source 10 provides at least two of a first constant voltage (e.g., positive voltage), a second constant voltage (e.g., negative voltage), and a ground voltage.

The pulse generating circuit 20 uses the voltages provided by the constant voltage source 10 to generate an intermediate voltage. The intermediate voltage may be a non-sinusoidal waveform such as a square wave. For the sake of discussion, the description below assumes that the intermediate voltage is a square wave, but the example embodiments are not limited thereto. For example, it is understood by those skilled in the art that the present disclosure may be equally applied to other types of waveforms including, for instance, a square wave containing a overshoot component.

The clamping circuit 30 may generate an output voltage by minimizing signal overshoot (or ringing) of the output voltage Vp.

Referring to FIG. 2, the constant voltage source 10 includes a first constant voltage generator 110 and a second constant voltage generator 120. The first constant voltage generator 110 may be connected between a ground and a first voltage node NV1, and the second constant voltage generator 120 may be connected between the ground and a second voltage node NV2. The first constant voltage generator 110 generates a first constant voltage (positive voltage, V_{DC1}), and the second constant voltage generator 120 generates a second constant voltage (negative voltage, V_{DC2}).

The pulse generating circuit 20 includes a first switch S1, a second switch S2, a third switch S3, and a fourth switch S4 sequentially connected between the first voltage node NV1 and the second voltage node NV2. The on/off of each of the plurality of switches S1, S2, S3, and S4 may be controlled by the controller.

The first switch S1 may be connected between the first voltage node NV1 and a first node N1. The second switch S2 may be connected between the first node N1 and a third node N3. The third switch S3 may be connected between the third node N3 and a second node N2. The fourth switch S4 may be connected between the second node N2 and the second voltage node NV2.

As illustrated, each of the switches S1, S2, S3, and S4 may be implemented as a transistor and may have body diodes D_{S1}, D_{S2}, D_{S3}, and D_{S4}, respectively. It is illustrated in the drawing that each of the switches S1, S2, S3, and S4 may be implemented as one switch, but the example embodiments are not limited thereto. For example, each of the switches S1, S2, S3, and S4 may have a plurality of MOS transistors or a plurality of insulated gate bipolar transistors (IGBT) connected in series are may be configured for operating under high voltage. The transistors connected in series may be configured to be simultaneously turned on by one (single) signal (gate signal).

With the first switch S1 and the second switch S2 turned on, the first constant voltage V_{DC1} from the first constant voltage generator 110 may be provided to the third node N3 through the first switch S1 and the second switch S2.

With the third switch S3 and the fourth switch S4 turned on, the second constant voltage V_{DC2} from the second constant voltage generator 120 may be provided to the third node N3 through the third switch S3 and the fourth switch S4.

Additionally, the pulse generating circuit 20 may further include a first diode D1 connected between the ground and the first node N1, and a second diode D2 connected between the ground and the second node N2. With the second switch S2 and the third switch S3 turned on, a voltage of the third node N3 may be grounded. It is illustrated in the drawing that each of the diodes D1 and D2 may be implemented as one diode, but the example embodiments are not limited thereto. For example, each of the diodes D1 and D2 may have a plurality of diodes connected in series to withstand a high operating voltage.

The clamping circuit 30 may be connected between at least one of the first node N1 and the second node N2 and an output node Np, and may remove, minimize or reduce the overshoot component of the output voltage Vp. For example, the clamping circuit 30 includes a first clamping diode D_{C1} connected between the first node N1 and the output node Np, and a second clamping diode D_{C2} connected between the second node N2 and the output node Np. It is illustrated in the drawing that each of the clamping diodes D_{C1} and D_{C2} may be implemented using one (or single) diode, but the example embodiments are not limited thereto. For example, each of the clamping diodes D_{C1} and D_{C2} may have a plurality of diodes connected in series to withstand a high operating voltage.

A parasitic inductor exists between the third node N3 and the output node Np, and the parasitic inductor and a capacitor Cp of a load may cause resonance. Accordingly, an unwanted or undesirable waveform such as overshoot may occur in the output voltage Vp. However, according to some example embodiments of the present disclosure, when overshoot occurs, overcurrent flows through the first clamping diode D_{C1} and/or the second clamping diode D_{C2}. Therefore, overshoot (or ringing) in the output voltage Vp may be reduced or minimized.

Additionally, an inductor Lr may be connected between the third node N3 and the output node Np. The inductor Lr may be for soft switching and may prevent, minimize, or reduce relatively large current from flowing to the output node Np in a relatively short duration. A current i_{Lr} may refer to a current flowing through the inductor Lr.

A load may be connected to the output node Np, and the load is represented by a resistor Rp and a capacitor Cp. The load may be, for example, a chamber in which a plasma process may be performed.

A voltage of the third node N3 may be represented as an intermediate voltage Vm, and the voltage and current provided to the load may be represented as an output voltage Vp and an output current ip.

Here, referring to FIG. 3, the graph on the left illustrates a case where the clamping circuit 30 is not used in the pulse generator 1, and the graph on the right illustrates a case where the clamping circuit 30 may be applied to the pulse generator 1 as illustrated in FIG. 1.

It is assumed that the intermediate voltage Vm may be a bipolar pulse swinging between +V_{DC1} and −V_{DC2}. When the clamping circuit 30 is not used in the pulse generator 1, overshoot occurs around +V_{DC1} and −V_{DC2} of the output voltage Vp, as illustrated in the graph on the left. When the clamping circuit 30 may be used in the pulse generator 1, as illustrated in the graph on the right, it may be seen that overshoot is minimized, prevented, or reduced around +V_{DC1} and −V_{DC2} of the output voltage Vp.

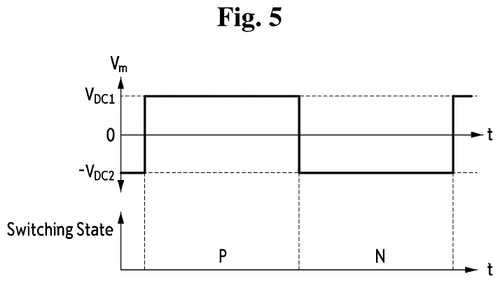

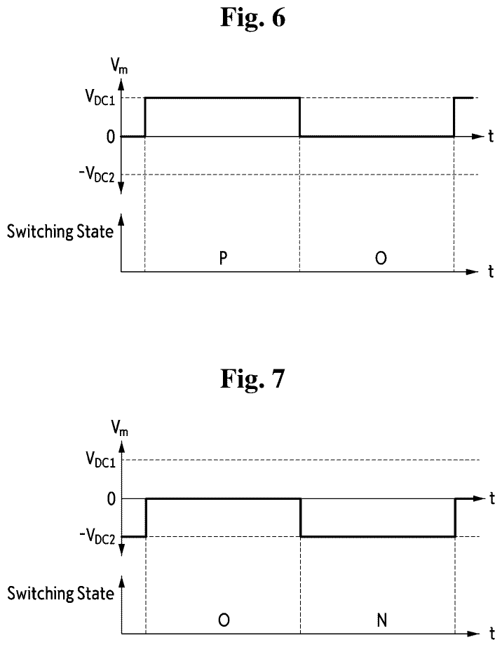

Hereinafter, an operation of the pulse generator, according to some example embodiments of the present disclosure, will be described with reference to FIGS. 2 and 4 to 7. FIG. 4 is a timing diagram of a three-level pulse generated according to a change in a switching state of the pulse generator. FIG. 5 is a timing diagram of a bipolar pulse generated according to a change in the switching state of the pulse generator. FIG. 6 is a timing diagram of a unipolar pulse generated according to a change in the switching state of the pulse generator. FIG. 7 is a timing diagram of a unipolar pulse generated according to a change in the switching state of the pulse generator.

As illustrated in Table 1 below, the pulse generator may have a plurality of switching states depending on the on/off states of the four switches (S1, S2, S3, and S4 in FIG. 2).

In the switching state P, the first switch S1 and the second switch S2 are turned on, and the third switch S3 and the fourth switch S4 are turned off. In the switching state P, the intermediate voltage Vm of the third node N3 is V_{DC1}.

In the switching state O, the second switch S2 and the third switch S3 are turned on, and the first switch S1 and the fourth switch S4 are turned off. In the switching state O, the intermediate voltage Vm of the third node N3 is the ground voltage (0 V).

In the switching state N, the third switch S3 and the fourth switch S4 are turned on, and the first switch S1 and the second switch S2 are turned off. In the switching state N, the intermediate voltage Vm of the third node N3 is −V_{DC2}.

In the switching state P′, the first switch S1 is turned on, and the second switch S2, the third switch S3, and the fourth switch S4 are turned off.

In the switching state N′, the fourth switch S4 is turned on, and the first switch S1, the third switch S3, and the fourth switch S4 are turned off.

In the switching state D, the first switch S1, the second switch S2, the third switch S3, and the fourth switch S4 are turned off.

TABLE 1

| Switching State | S1 | S2 | S3 | S4 | Vm |
|---|---|---|---|---|---|
| P | on | on | off | off | V_{DC1} |
| O | off | on | on | off | 0 V |
| N | off | off | on | on | −V_{DC2} |
| P′ | on | off | off | off | — |
| N′ | off | off | off | on | — |
| D | off | off | off | off | — |

Referring to FIGS. 2 and 4, it will be described that the pulse generator generates a 3-level pulse.

The intermediate voltage Vm of the third node N3 is V_{DC1} in the switching state P, 0 V in the switching state O, and −V_{DC2} in the switching state N. As the switching state P, the switching state O, the switching state N, and the switching state O are switched in order (or successively), the intermediate voltage Vm has values V_{DC1}, 0 V, −V_{DC2}, and 0 V. Therefore, the pulse generator generates a three-level pulse that changes from V_{DC1} to 0 V and to and −V_{DC2} over time.

Referring to FIGS. 2 and 5, it will be described that the pulse generator generates a bipolar pulse.

As the switching state P and the switching state N are alternated, the intermediate voltage Vm switches between V_{DC1} and −V_{DC2}. Therefore, the pulse generator generates a bipolar pulse that alternates between V_{DC1} and −V_{DC2}.

Referring to FIGS. 2 and 6, it will be described that the pulse generator generates a unipolar pulse.

As the switching state P and the switching state O are alternated, the intermediate voltage Vm switches between V_{DC1} and 0 V. Therefore, the pulse generator generates a bipolar pulse that alternates between V_{DC1} and 0 V.

Referring to FIGS. 2 and 7, it will be described that the pulse generator generates a unipolar pulse.

As the switching state O and the switching state N are alternated, the intermediate voltage Vm switches between 0 V and −V_{DC2}. Therefore, the pulse generator generates a bipolar pulse that alternates between to 0 V and −V_{DC2}.

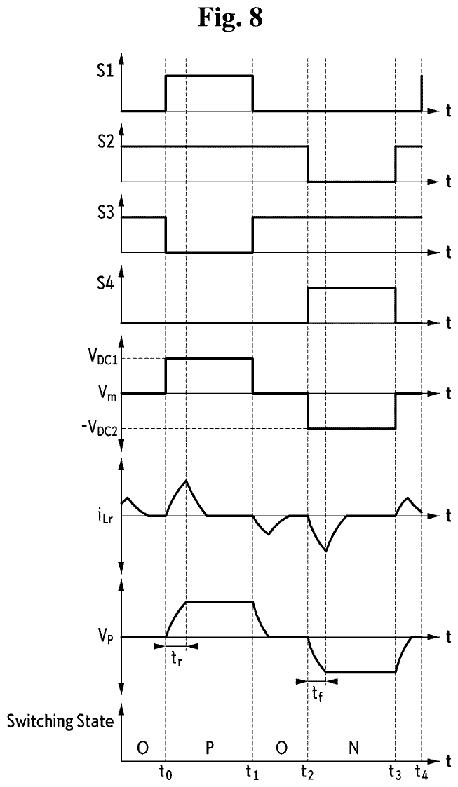

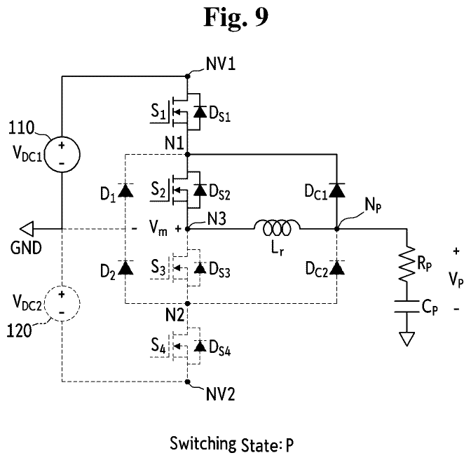

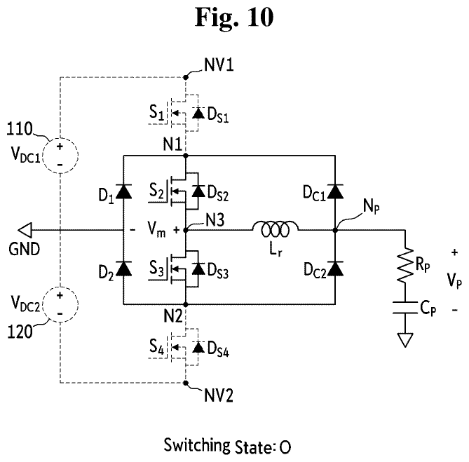

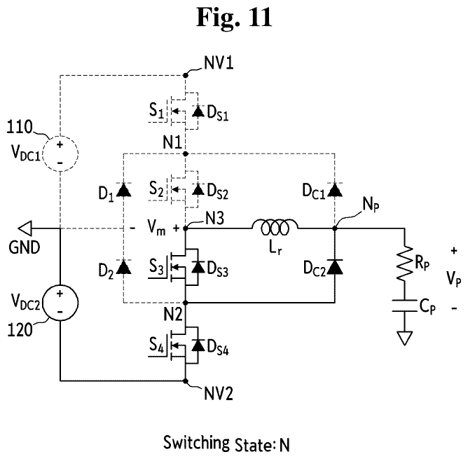

The three-level pulse generation operation of the pulse generator will be described in more detail with reference to FIGS. 8 to 11. FIG. 8 is a timing diagram of a three-level pulse generation operation of the pulse generator. FIG. 9 illustrates a mode analysis of the pulse generator in a switching state P. FIG. 10 illustrates a mode analysis of the pulse generator in a switching state O. FIG. 11 illustrates a mode analysis of the pulse generator in a switching state N.

Referring to FIG. 8, between time t0 and time t1, the pulse generator is in a switching state P.

In switching state P, at time t0, the first switch S1 is turned on. The second switch S2 remains in an on state. The third switch S3 is turned off. The fourth switch S4 remains in an off state. Accordingly, the intermediate voltage Vm becomes V_{DC1}. The amount of current i_{Lr} increases in a positive direction. The output voltage Vp also increases. During a rise time tr, the output voltage Vp steadily increases and becomes V_{DC1}. When the rise time tr elapses, the magnitude of the current i_{Lr} begins to decrease, and the output voltage Vp maintains V_{DC1}.

Here, referring to FIG. 9, in the switching state P, since the first switch S1 and the second switch S2 are in the on state, the current is provided to the load through the first switch S1, the second switch S2, and the inductor Lr. The overshoot component in the output voltage Vp is removed, reduced, or minimized by the first clamping diode D_{C1}.

Referring again to FIG. 8, between time t1 and time t2, the pulse generator is in the switching state O.

In the switching state O, at time t1, the first switch S1 is turned off. The second switch S2 remains in an on state. The third switch S3 is turned on. The fourth switch S4 remains in an off state. Accordingly, the intermediate voltage Vm becomes 0 V. The current i_{Lr} increases in the negative direction from 0 A. The output voltage Vp decreases. When a predetermined or desired time elapses, the current i_{Lr} becomes 0 A again, and the output voltage Vp drops to 0 V.

Here, referring to FIG. 10, in the switching state O, since the first switch S1 and the fourth switch S4 are in the off state, and the second switch S2 and the third switch S3 are in the on state, the intermediate voltage Vm of the third node N3 becomes 0 V. During the switching process of some switches S1 and S4, when the current i_{Lr} in the inductor Lr increases in the negative direction and the output voltage Vp reaches 0 V, the current i_{Lr} decreases and no longer flows. In this case, the overshoot component in the output voltage Vp is removed, reduced, or minimized by the first clamping diode D_{C1} and the second clamping diode D_{C2}.

Referring again to FIG. 8, between time t2 and time t3, the pulse generator is in the switching state N.

In switching state N, at time t2, the first switch S1 is in an off state, the second switch S2 is turned off, the third switch S3 is in an on state, and the fourth switch S4 is turned on. Accordingly, the intermediate voltage Vm becomes −V_{DC2}. The current i_{Lr} increases in the negative direction. The output voltage Vp also decreases. During a fall time t_{f}, the output voltage Vp steadily decreases and becomes −V_{DC2}. When the fall time t_{f} elapses, the magnitude of the current i_{Lr} begins to decrease, and the output voltage Vp maintains −V_{DC2}.

Here, referring to FIG. 11, in the switching state N, since the third switch S3 and the fourth switch S4 are in the on state, the current is provided to the load through the third switch S3, the fourth switch S4, and the inductor Lr. The overshoot component in the output voltage Vp is removed, reduced, or minimized by the second clamping diode D_{C2}.

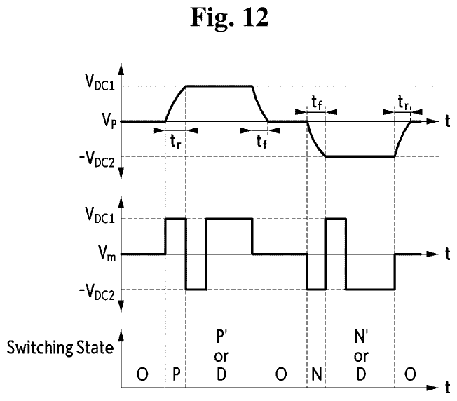

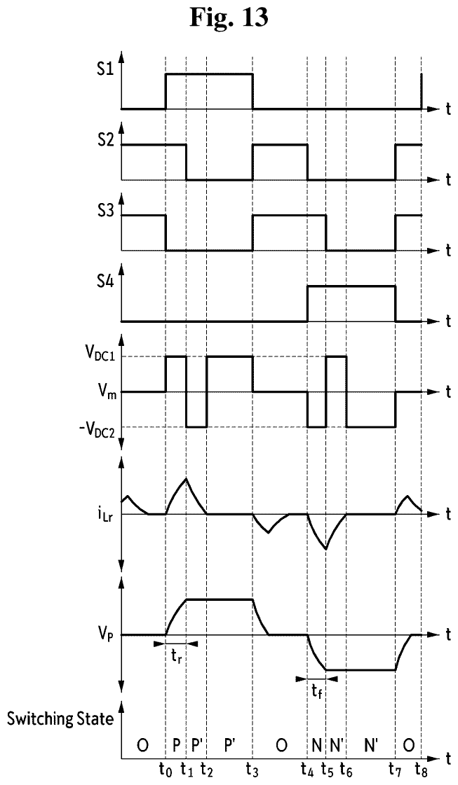

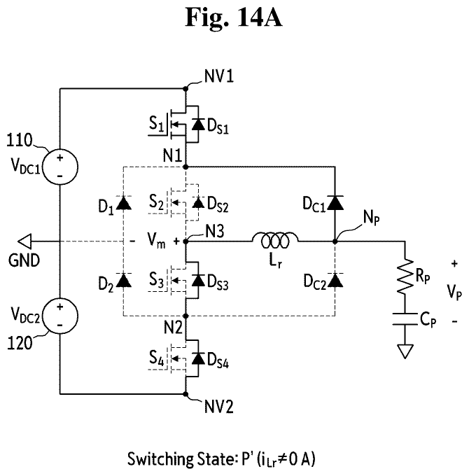

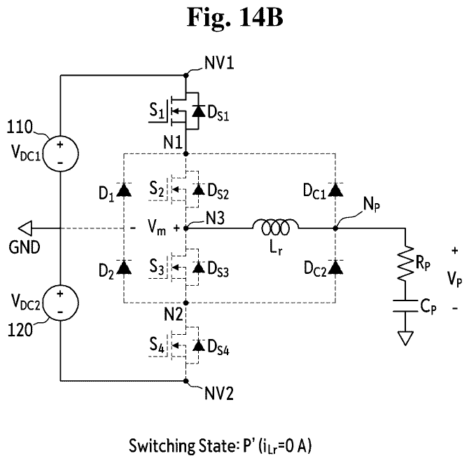

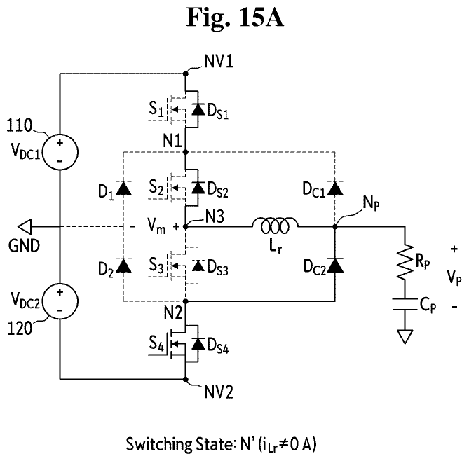

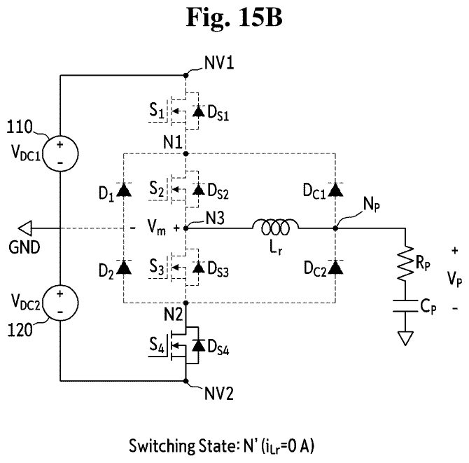

The three-level pulse generation operation of the pulse generator 1 will be described in detail with reference to FIGS. 12 to 15B. Energy regeneration is performed together with the three-level pulse generation operation. FIG. 12 is a timing diagram of a three-level pulse generated with energy regeneration according to a change in the switching state of the pulse generator 1. FIG. 13 is a timing diagram of a three-level pulse generation operation in which energy regeneration is performed together. FIGS. 14A and 14B illustrate mode analysis of the pulse generator in the switching state P′. FIGS. 15A and 15B illustrate mode analysis of the pulse generator in the switching state N′. The operation of the pulse generator in FIGS. 12 to 15 may be similar in some respects to the operation of the pulse generator 1 in FIGS. 8-11, and therefore may be best understood with reference thereto where like numerals indicate like elements not described again in detail.

Referring to FIG. 12, the pulse generator 1 generates a 3-level pulse, and energy regeneration may be performed in the process of generating the 3-level pulse.

The intermediate voltage Vm of the third node N3 is V_{DC1} in the switching state P, −V_{DC2} when the inductor current i_{Lr} is not 0 A and V_{DC1} when the inductor current i_{Lr} is 0 A in the switching state P′, 0 V in the switching state O, −V_{DC2} in the switching state N, and V_{DC1} when the inductor current i_{Lr} is not 0 A and −V_{DC2} when the inductor current i_{Lr} is 0 A in the switching state N′. In the switching state D, all switches S1 to S4 are in an off state, and the intermediate voltage Vm of the third node N3 shows the same aspect as the intermediate voltage Vm in the switching state P′ when the previous state is the switching state P, and the same aspect as the intermediate voltage Vm in the switching state N′ when the previous state is the switching state N.

As the switching state P, the switching state P′, the switching state O, the switching state N, the switching state N′, and the switching state O proceed in order (or successively), an order of transition of the intermediate voltage Vm may be V_{DC1}, −V_{DC2}, V_{DC1}, 0 V, −V_{DC2}, V_{DC1}, −V_{DC2}, and 0 V. Since the change in the intermediate voltage Vm during the energy regeneration process may not affect the output voltage Vp, the pulse generator generates a three-level pulse (output voltage Vp) that switches from V_{DC1} to 0 V, and to −V_{DC2}.

Here, the energy regeneration is performed in the switching state P′ and switching state N′ stages. This will be described in detail later with reference to FIGS. 14A, 14B, 15A, and 15B.

Alternatively, as the switching state P, the switching state D, the switching state O, the switching state N, the switching state D, and the switching state O proceed in order (or successively), an order of transition of the intermediate voltage Vm may be V_{DC1}, −V_{DC2}, V_{DC1}, 0 V, −V_{DC2}, V_{DC1}, −V_{DC2}, and 0 V. Since the change in the intermediate voltage Vm during the energy regeneration process may not affect the output voltage Vp, the pulse generator generates a three-level pulse (output voltage Vp) that may switch from V_{DC1} to 0 V, and to −V_{DC2}.

Referring to FIG. 13, between time t0 and time t1, the pulse generator is in the switching state P.

In the switching state P, at time to, the first switch S1 is turned on. The second switch S2 remains in an on state. The third switch S3 is turned off. The fourth switch S4 remains in an off state. Accordingly, the intermediate voltage Vm becomes V_{DC1}. During a rise time tᵣ, the output voltage Vp steadily increases and becomes V_{DC1}.

Between time t1 and time t2 the pulse generator is in the switching state P′.

In the switching state P′, at time t1, the second switch S2 is turned off. The remaining switches S1, S3, and S4 maintain their previous states. Accordingly, the magnitude of the current i_{Lr} decreases, the intermediate voltage Vm changes to −V_{DC2}, and the output voltage Vp maintains V_{DC1}.

Here, referring to FIG. 14A, the current is supplied to the second constant voltage generator 120 and the first constant voltage generator 110 through the second voltage node NV2, the body diode D_{S4} of the fourth switch S4, the body diode D_{S3} of the third switch S3, the output node Np, the first clamping diode D_{C1}, the body diode D_{S1} of the first switch S1, and the first voltage node NV1. Accordingly, the second constant voltage generator 120 and the first constant voltage generator 110 are charged and the energy regeneration is performed.

Referring again to FIG. 13, between time t2 and time t3, the pulse generator is in the switching state P′. Referring to FIG. 14B, the inductor current i_{Lr} remains at 0 A, the intermediate voltage Vm changes to V_{DC1}, and the output voltage Vp remains at V_{DC1}.

Between time t3 and time t4 the pulse generator is in the switching state O.

Specifically, at time t3, the first switch S1 is turned off, the second switch S2 is turned on, the third switch S3 is turned on, and the fourth switch S4 maintains the off state. When the current i_{Lr} increases in the negative direction and the output voltage Vp reaches 0 V, the current i_{Lr} decreases and no longer flows.

Between time t4 and time t5 the pulse generator is in the switching state N.

In the switching state N, at time t4, the second switch S2 is turned off and the fourth switch S4 is turned on. The remaining switches S1 and S3 maintain their previous states. Accordingly, the intermediate voltage Vm becomes −V_{DC2}. The current i_{Lr} increases in the negative direction. The output voltage Vp also steadily decreases during the fall time tr and becomes −V_{DC2}.

Between time t5 and time t6 the pulse generator is in the switching state N′.

In switching state N′, at time t5, the third switch S3 is turned off, and the remaining switches S1, S2, and S4 maintain their previous states. Accordingly, the magnitude of the current i_{Lr} decreases, the intermediate voltage Vm changes to V_{DC1}, and the output voltage Vp maintains −V_{DC2}.

Here, referring to FIG. 15A, a negative current is supplied to the first constant voltage generator 110 and the second constant voltage generator 120 through the body diode D_{S1} of the first switch S1, the body diode D_{S2} of the second switch S2, the output node Np, the second clamping diode D_{C2}, and the body diode D_{S4} of the fourth switch S4. Accordingly, the first constant voltage generator 110 and the second constant voltage generator 120 are charged and the energy regeneration is performed.

Referring again to FIG. 13, between time t6 and time t7, the pulse generator is in the switching state N′. Referring to FIG. 15B, the inductor current i_{Lr} remains at 0 A, the intermediate voltage Vm changes to −V_{DC2}, and the output voltage Vp remains at −V_{DC2}.

Between time t7 and time t8 the pulse generator is in the switching state O.

At time t7, the second switch S2 is turned on, the third switch S3 is turned on, the fourth switch S4 is turned off, and the first switch S1 maintains the previous state. Accordingly, the intermediate voltage Vm becomes 0 V, and the output voltage Vp also becomes 0 V.

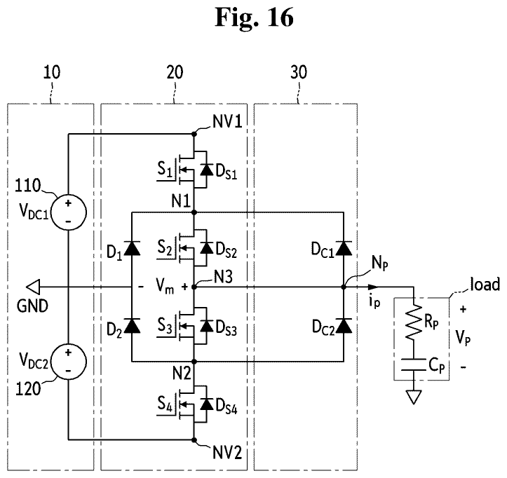

FIGS. 16 to 19 are circuit diagrams of pulse generators according to some example embodiments of the present disclosure. The structure and/or operation of the pulse generators in FIGS. 16 to 19 may be similar in some respects to structure and/or operation of the pulse generators of FIGS. 1 to 15B, and therefore may be best understood with reference thereto where like numerals indicate like elements not described again in detail.

In the pulse generator illustrated in FIG. 16, a separate inductor Lr may be absent between the third node N3 and the output node Np. A parasitic inductor may exist between the third node N3 and the output node Np.

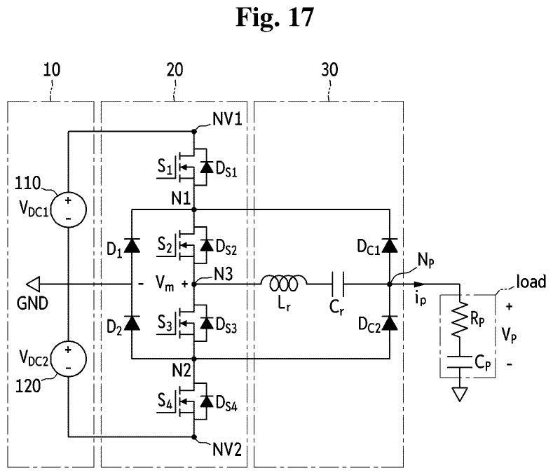

The pulse generator illustrated in FIG. 17 may further include a variable capacitor Cr connected between the third node N3 and the output node Np. The controller may change a resonant frequency of an output current iₚ by adjusting a capacitance of the variable capacitor Cr.

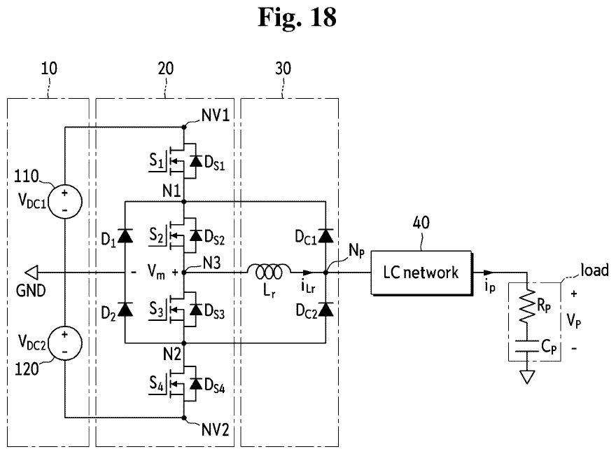

The pulse generator illustrated in FIG. 18 may further include an LC network connected to the output node Np. By adjusting the LC network, the controller may vary an impedance as seen from the output node Np.

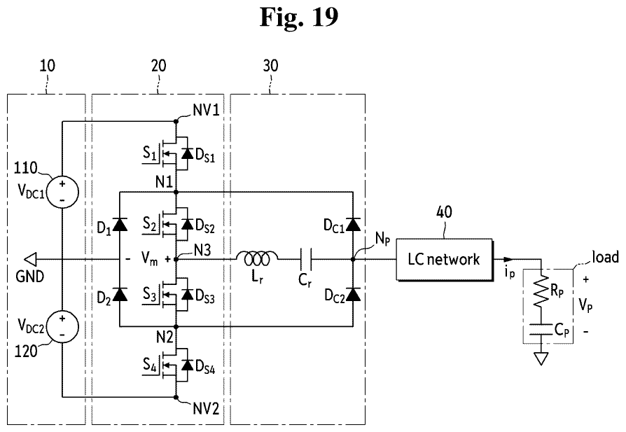

The pulse generator illustrated in FIG. 19 may further include a variable capacitor Cr connected between the third node N3 and the output node Np, and an LC network connected to the output node Np.

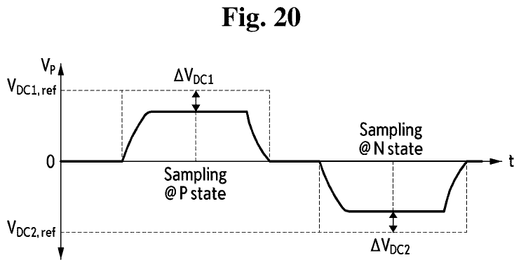

Hereinafter, a feedback operation of the pulse generator will be described with reference to FIGS. 20 to 22.

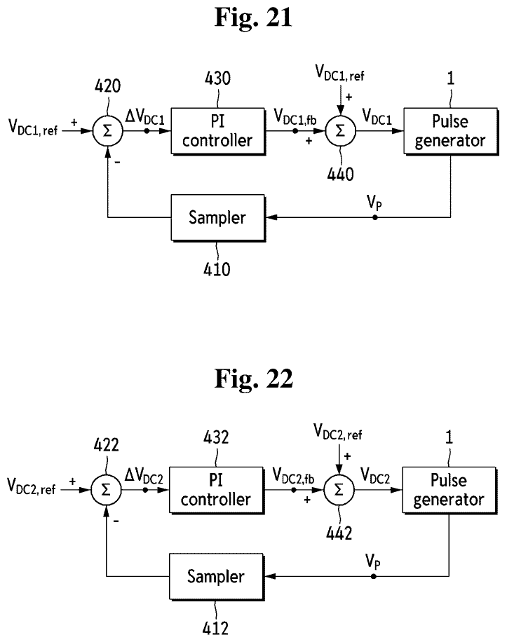

FIG. 20 is a timing diagram of a feedback operation of the pulse generator 1 according to some example embodiments of the present disclosure. FIG. 21 is an example block diagram for feedback control of a first constant voltage V_{DC1} of the pulse generator 1 according to some example embodiments of the present disclosure. FIG. 22 is an example block diagram for feedback control of a second constant voltage V_{DC2} of the pulse generator 1 according to some example embodiments of the present disclosure.

Referring to FIG. 20, the output voltage Vp is sampled in the switching state P of the pulse generator. The controller calculates a first difference value ΔV_{DC1} by comparing the sampled value with a first reference voltage V_{DC1,ref}. The magnitude of the first constant voltage V_{DC1} may be adjusted based on the first difference value ΔV_{DC1}.

Referring to FIG. 21, a controller 430 based on proportional-integral (PI) control may be used to implement the above-described operations. In some example embodiments, the controller 430 may be implemented based on one or more of proportional control, integral control, and differential control.

The first constant voltage generator 110 of the pulse generator 1 may include a sampler 410, a first calculator 420, a PI controller 430, and a second calculator 440. The sampler 410 samples the output voltage Vp in the switching state P of the pulse generator 1. The first calculator 420 outputs the first difference value ΔV_{DC1} by comparing the first reference voltage V_{DC1,ref} and the sampled value. The PI controller 430 generates a first feedback value V_{DC1,fb} based on the first difference value ΔV_{DC1}. The second calculator 440 generates a first constant voltage V_{DC1} level by calculating the first reference voltage V_{DC1,ref} and the first feedback value V_{DC1,fb}. The first constant voltage V_{DC1} level is provided to the pulse generator 1 and used to adjust or generate pulses. The first constant voltage generator 110 of the pulse generator 1 adjusts or generates the first constant voltage V_{DC1} according to the provided first constant voltage level.

Referring again to FIG. 20, the output voltage Vp is sampled in the switching state N of the pulse generator. The controller calculates a second difference value ΔV_{DC2} by comparing the sampled value with a second reference voltage V_{DC2,ref}. The magnitude of the second constant voltage V_{DC2} may be adjusted based on the second difference value ΔV_{DC2}.

Here, referring to FIG. 22, a controller 432 based on proportional-integral (PI) control may be used to implement the above-described operations. In some example embodiments, the controller 432 may be implemented based on one or more of proportional control, integral control, and differential control.

The second constant voltage generator 120 of the pulse generator 1 may include a sampler 412, a third calculator 422, a PI controller 432, and a fourth calculator 442. The sampler 412 samples the output voltage Vp in the switching state N of the pulse generator 1. The third calculator 422 outputs the second difference value ΔV_{DC2} by comparing the second reference voltage V_{DC2,ref} and the sampled value. The PI controller 432 generates a second feedback value V_{DC2,fb} based on the second difference value ΔV_{DC2}. The fourth calculator 442 generates a second constant voltage V_{DC2} level by calculating the second reference voltage V_{DC2,ref} and the second feedback value V_{DC2,fb}. The second constant voltage V_{DC2} level is provided to the pulse generator 1 and used to adjust or generate pulses. The second constant voltage generator 120 of the pulse generator 1 generates the second constant voltage V_{DC2} according to the provided second constant voltage level.

In FIGS. 20 to 22, the feedback control method was applied to both the first constant voltage V_{DC1} and the second constant voltage V_{DC2}, but, some example embodiments, the feedback control method may be applied to only one of the first constant voltage V_{DC1} and the second constant voltage V_{DC2}.

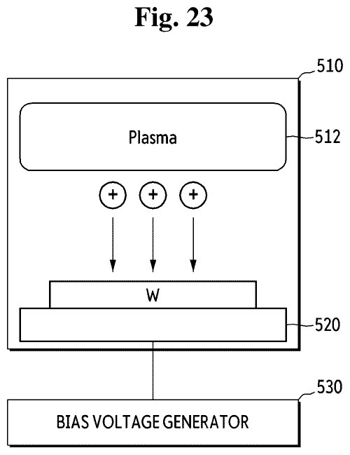

FIG. 23 is a block diagram of a substrate processing device according to some example embodiments of the present disclosure. The discussion related to the substrate processing device may be best understood with reference to FIGS. 1 to 22.

Referring to FIG. 23, the substrate processing device includes a chamber 510, a wafer support 520, and a bias voltage generator 530. The substrate processing device may be a plasma generation device for performing etching or cleaning operations on a substrate W positioned in the chamber 510. However, other operations may also be performed using the substrate processing device.

The chamber 510 is a space or volume in which a plasma process is performed. The plasma 512 may be a capacitively coupled plasma (CCP), an inductively coupled plasma (ICP), a dual frequency CCP, or a remote plasma source (RPS) or the like.

The support 520 is installed inside the chamber 510 and is used to secure or support the substrate W to be processed. The support 520 may be, for example, an electrostatic chuck, or similar device.

The bias voltage generator 530 applies a bias voltage to an electrode connected to the support 520. The bias voltage is used to provide directionality to ions of the plasma 512. For example, the bias voltage may pull positive ions of the plasma 512 toward the substrate W. The bias voltage generator 530 may be implemented as the pulse generator described with reference to FIGS. 1 to 22.

For example, the bias voltage generator 530 may include the first constant voltage generator 110 connected to the first voltage node NV1, the second constant voltage generator 120 connected to the second voltage node NV2, the first switch S1 connected between the first voltage node NV1 and the first node N1, the second switch S2 connected between the first node N1 and the third node N3, the third switch S3 connected between the third node N3 and the second node N2, the fourth switch S4 connected between the second node N2 and the second voltage node NV2, and the clamping circuit 30 connected between at least one of the first node N1 and the second node N2 and the output node Np and removing the overshoot of the voltage signal Vp output through the third node N3 and the output node Np, as illustrated in FIG. 2.

The clamping circuit 30 includes a first clamping diode D_{C1} connected between the first node N1 and the output node Np, and a second clamping diode D_{C2} connected between the second node N2 and the output node Np.

The bias voltage generator 530 has been described as being connected to the electrode connected to the support 520, but is not limited thereto. For example, bias voltage generator 530 may also be connected to an upper electrode.

While several example embodiments have been provided in the present disclosure, it should be understood that the disclosed devices, systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another device or system, or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A pulse generator comprising:
a first constant voltage generator connected to a first voltage node;
a second constant voltage generator connected to a second voltage node;
a first switch connected between the first voltage node and a first node;
a second switch connected between the first node and a third node;
a third switch connected between the third node and a second node;
a fourth switch connected between the second node and the second voltage node; and
a clamping circuit connected between at least one of the first node and the second node and an output node, and configured to reduce an overshoot of an output voltage that is output through the third node and the output node.

2. The pulse generator of claim 1, wherein the clamping circuit includes a first clamping diode connected between the first node and the output node.

3. The pulse generator of claim 2, wherein the clamping circuit further includes a second clamping diode connected between the second node and the output node.

4. The pulse generator of claim 1, further comprising:
a first diode connected between the first node and a ground; and
a second diode connected between the second node and the ground.

5. The pulse generator of claim 1, further comprising an inductor connected between the third node and the output node.

6. The pulse generator of claim 5, further comprising a variable capacitor connected between the third node and the output node.

7. The pulse generator of claim 1, further comprising an LC network connected to the output node.

8. The pulse generator of claim 1, wherein in a first switching state, the first switch and the second switch are configured to be in an on state, and the third switch and the fourth switch are configured to be in an off state,
in a second switching state, the first switch and the second switch are configured to be in an off state, and the third switch and the fourth switch are configured to be in an on state, and
the pulse generator is configured to generate the output voltage by alternately switching between the first switching state and the second switching state.

9. The pulse generator of claim 1, wherein in a first switching state, the first switch and the second switch are configured to be in an on state, and the third switch and the fourth switch are configured to be in an off state,
in a second switching state, the second switch and the third switch are configured to be in an on state, and the first switch and the fourth switch are configured to be in an off state, and
the pulse generator is configured to generate the output voltage by alternately switching between the first switching state and the second switching state.

10. The pulse generator of claim 1, wherein in a first switching state, the first switch and the second switch are configured to be in an on state, and the third switch and the fourth switch configured to be are in an off state,
in a second switching state, the second switch and the third switch are configured to be in an on state, and the first switch and the fourth switch are configured to be in an off state,
in a third switching state, the first switch and the second switch are configured to be in an off state, and the third switch and the fourth switch are configured to be in an on state, and
the pulse generator is configured to generate the output voltage by successively switching between the first switching state, the second switching state, the third switching state, and the second switching state.

11. The pulse generator of claim 1, wherein in a first switching state, the first switch and the second switch are configured to be in an on state, and the third switch and the fourth switch are configured to be in an off state,
in a second switching state, the first switch is configured to be in an on state, and the second switch, the third switch, and the fourth switch are configured to be in an off state, and
the pulse generator is configured to switch to the second switching state immediately following the first switching state.

12. The pulse generator of claim 11, wherein a duration of the second switching state is longer than a duration of the first switching state.

13. The pulse generator of claim 1, wherein in a first switching state, the first switch and the second switch are configured to be in an on state, and the third switch and the fourth switch are configured to be in an off state,
in a second switching state, the first switch, the second switch, the third switch, and the fourth switch are configured to be in an off state,
in a third switching state, the second switch and the third switch are configured to be in an on state, and the first switch and the fourth switch are configured to be in an off state, and
the pulse generator is configured to sequentially switch between the first switching state, the second switching state, and the third switching state.

14. The pulse generator of claim 1, wherein in a first switching state, the first switch and the second switch are configured to be in an on state, and the third switch and the fourth switch are configured to be in an off state, and
the first constant voltage generator includes:
a sampler configured to sample the output voltage in the first switching state,
a first calculator configured to generate a difference value by comparing a sampled value of the output voltage and a reference voltage,
a PI controller configured to generate a feedback value based on the difference value, and
a second calculator configured to generate a first constant voltage by calculating the reference voltage and the feedback value.

15. A pulse generator comprising:
a constant voltage source including a first constant voltage generator and a second constant voltage generator;
a pulse generating circuit including a first switch connected between a first node and the first constant voltage generator, a second switch connected between the first node and a third node, a third switch connected between the third node and a second node, a fourth switch connected between the second node and the second constant voltage generator, a first diode connected between a ground and the first node, and a second diode connected between the ground and the second node; and
a clamping circuit including a first clamping diode connected between the first node and an output node, a second clamping diode connected between the second node and the output node, and an inductor connected between the third node and the output node, wherein
an output voltage is output through the output node, and the output voltage includes signals generated by sequentially switching between a first switching state, a second switching state, and a third switching state,
in the first switching state, the first switch and the second switch are configured to be in an on state, and the third switch and the fourth switch are configured to be in an off state,
in the second switching state, the first switch is configured to be in an on state, and the second switch, the third switch, and the fourth switch are configured to be in an off state, and
in the third switching state, the second switch and the third switch are configured to be in an on state, and the first switch and the fourth switch are configured to be in an off state.

16. The pulse generator of claim 15, wherein a duration of the second switching state is longer than a duration of the first switching state.

17. The pulse generator of claim 15, further comprising an LC network connected to the output node.

18. The pulse generator of claim 15, further comprising a variable capacitor connected between the third node and the output node.

19. The pulse generator of claim 15, wherein the first constant voltage generator includes:
a sampler configured to sample the output voltage in the first switching state,
a first calculator configured to generate a difference value by comparing a sampled value of the output voltage and a reference voltage,
a PI controller configured to generate a feedback value based on the difference value, and
a second calculator configured to generate a first constant voltage by calculating the reference voltage and the feedback value.

20. A pulse generator comprising:
a first constant voltage generator connected to a first voltage node;
a second constant voltage generator connected to a second voltage node;
a first switch connected between the first voltage node and a first node;
a second switch connected between the first node and a third node;
a third switch connected between the third node and a second node;
a fourth switch connected between the second node and the second voltage node;
a first clamping diode connected between the first node and an output node; and
a second clamping diode connected between the second node and the output node, wherein
each of the first, second, third, and fourth switches includes a MOS transistor,
when the first switch and the second switch are configured to be in an on state, the pulse generator is configured to output an output voltage through the first switch, the second switch, the third node, and the output node, and
when the second switch is configured to be in an off state, a current is supplied to the second constant voltage generator and the first constant voltage generator through the second voltage node, a body diode of the fourth switch, a body diode of the third switch, the output node, the first clamping diode, and a body diode of the first switch.
